(19) United States
(12) Patent Application Publication
(10) Pub. No.: US 2011/0273944 A1
(43) Pub. Date: Nov. 10, 2011

(54) SEMICONDUCTOR MEMORY DEVICE AND METHOD OF OPERATING THE SAME

(76) Inventor: Jin Su PARK, Daegu (KR)

(21) Appl. No.: 12/982,274

(22) Filed: Dec. 30, 2010

(30) Foreign Application Priority Data
May 10, 2010 (KR) 10-2010-0043448

(51) Int. Cl. G11C 7/00; G11C 7/10

(52) U.S. Cl. 365/189.15; 365/189.05; 365/189.16

(57) ABSTRACT

A semiconductor memory device includes first and second planes having a memory cell array that includes a plurality of memory cells coupled to bit lines, and page buffer groups that are coupled respectively to one or more of the bit lines and each include page buffers, and a common input/output circuit shared by the page buffer groups of the first and second planes for data input/output control, and coupled to data input/output pads.

### CROSS-REFERENCE TO RELATED APPLICATIONS

The present application claims priority under 35 U.S.C 119(a) to Korean Application No. 10-2010-0043448, filed on May 10, 2010, in the Korean Intellectual Property Office, which is incorporated by reference in its entirety.

### BACKGROUND

1. Technical Field

Embodiments of the present invention relate to a semiconductor memory device and method of operating the semiconductor memory device.

2. Related Art

The industrial and commercial demands for semiconductor memories capable of electrically programming and erasing, and reserving data without power supply are increasing. Accordingly, the technology toward higher integration density of memory cells has been advanced for the purpose of obtaining memory having a larger data capacity. As one of the semiconductor memories, a nonvolatile memory device is generally equipped with a plurality of cell strings, each of which is formed of a plurality of memory cells coupled in series.

The plural cell strings constitute one memory block.

A traditional semiconductor memory device has been structured by placing all memory blocks on a single plane, which is called ‘single plane structure’. Here, a memory block is the unit of erasing operation. Each memory block contains a plurality of memory cells.

In a flash memory with the single plane structure, every erasing operation is conducted to one block. But programming and reading operations perform on a page basis.

On the other hand, there has been proposed a multi-plane structure in order to enhance performance of the semiconductor memory. In a multi-plane semiconductor memory device, memory blocks are uniformly dispersed over a plurality of planes. Such a multi-plane structure is known as useful for simultaneously erasing, programming and reading blocks or pages which are located in different positions from each other. The memory blocks operated at the same time are continuously arranged over adjacent planes.

Semiconductor memory devices are being improved in terms of higher integration density, larger data capacity and bigger chip size. However, these improvements are accompanied by an increase in the number of planes. Such functional improvement technically goes with a scale-down of design rule (e.g., circuit line pitch), an increase of fabrication steps, and higher difficulty of processing. These disadvantages with respect to fabrication act as factors that may degrade product yields of semiconductor memory devices.

### SUMMARY

Accordingly, exemplary embodiments of the present invention are directed to a semiconductor memory device capable of reducing dimensions occupied by data input/output circuits by consolidating circuits, which function to input/output data onto one plane.

In an exemplary embodiment, a semiconductor memory device may be comprised of first and second planes each comprising a memory cell array that includes a plurality of memory cells coupled to bit lines, and page buffer groups that are coupled respectively to one or more of the bit lines and each include page buffers, and a common input/output circuit shared by the page buffer groups of the first and second planes for data input/output control, and coupled to data input/output pads.

In another exemplary embodiment, a semiconductor memory device may be comprised of a first plane comprising a first memory cell array that includes a plurality of first memory cells coupled to bit lines, and a first page buffer group that is coupled to one or more of the bit lines and has page buffers, and a second plane comprising a second memory cell array that includes a plurality of second memory cells coupled to the bit lines, a second page buffer group that is coupled to one or more of the bit lines and includes page buffers, and an input/output circuit coupled between the second page buffer group and data input/output pads to control data input/output. The first and second memory cells may share the bit lines.

In another exemplary embodiment, a semiconductor memory device may be comprised of a first plane that comprises a first memory cell array including a plurality of first memory cells, and a first page buffer group including page buffers coupled to first bit lines to which the first memory cells are electrically connected, a second plane that comprises a second memory cell array including a plurality of second memory cells, a second page buffer group including page buffers coupled to second bit lines to which the second memory cells are electrically connected, and an input/output circuit coupled between the second page buffer group and data input/output pads for data input/output control, and a bit-line connection circuit configured to electrically connect the first bit lines with the second bit lines in response to a control signal.

In still another exemplary embodiment, a method of programming a semiconductor memory device may be comprised of inputting data, which is to be programmed into a first plane, into a second page buffer group included in a second plane, transferring data from the second page buffer group to a first page buffer group of the first plane through bit lines that are jointly coupled to the first and second planes, and programming the first plane with data that are transferred into the first page buffer group.

Still another exemplary embodiment provides a method of reading a semiconductor memory device, which may be comprised of reading data from a selected page of a first plane and storing the read data into a first page buffer group of the first plane, transferring the read data from the first page buffer group to a second page buffer group of a second plane through bit lines that are jointly coupled to the first and second planes, and outputting the transferred data to an external system from the second page buffer group through an input/output circuit that is included in the second plane.

In the reading method, transferring data may be comprised of changing voltages of the bit lines coupled respectively by the data that have been input into the second page buffer group, and storing data, which are sensed through the bit lines with the changed voltages, into the first page buffer group.

The reading method may be further comprised of reading data from a selected page of a second plane and storing the read data into the second page buffer group, and outputting the read data to an external system from the second page buffer group through the input/output circuit.

According to the exemplary embodiments of the semiconductor memory device and method of operating the same, circuits used for data input/output are consolidated into one section and the consolidated input/output circuits are shared by a plurality of planes, which is effective in lessening the complexity of interconnection lines to input/output pads.

A further understanding of the nature and advantages of the present invention herein may be realized by reference to the remaining specification and the attached drawings.

### BRIEF DESCRIPTION OF THE DRAWINGS

The present invention is illustrated by way of example, and not by way of limitation, in the figures of the accompanying drawings and in which like reference numbers refer to similar elements and in which:

FIG. 1 illustrates a general semiconductor memory device;

FIG. 2 illustrates a semiconductor memory device according to a first exemplary embodiment of the present invention;

FIG. 3 illustrates a semiconductor memory device according to a second exemplary embodiment of the present invention;

FIG. 4 is a circuit diagram illustrating an interconnection feature among the first and second page buffer groups, and the bit-line connection circuit, of FIG. 3; and

FIG. 5 is a timing diagram describing data transmission between the first and second page buffers of FIG. 4.

### DESCRIPTION OF EMBODIMENTS

Hereinafter, various exemplary embodiments will now be described more fully with reference to the accompanying drawings in which some exemplary embodiments are shown. However, specific structural and functional details disclosed herein are merely representative for purposes of describing exemplary embodiments of the present invention.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Further, it will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the invention. As used herein, the term “and/or” includes any and all combinations of one or more of the associated listed items. Also it should be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In order to more specifically describe exemplary embodiments, various aspects will be hereinafter described in detail with reference to the accompanying drawings.

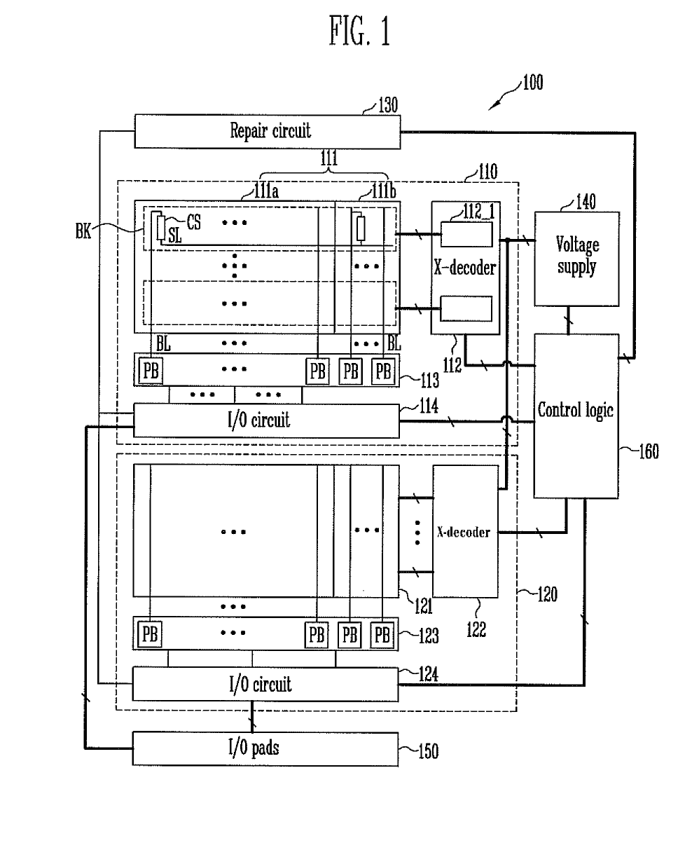

FIG. 1 illustrates a semiconductor memory device.

Referring to FIG. 1, a semiconductor memory device 100 is organized by generally including first and second planes 110 and 120, a repair circuit 130, an input/output pad group 140 and a control logic circuit 160.

The first plane 110 is similar to the second plane 120 in circuit formation and function.

The first plane 110 includes a memory cell array 111 composed of a main cell array 111a and a redundant cell array 111b, an X-decoder 112, a page buffer group 113 and an input/output circuit 114.

The main and redundant cell arrays, 111a and 111b, include memory cells for storing data. The memory cells of the main cell array 111a are referred to as main cells and the memory cells of the redundant cell array 111b are referred to as redundant cells.

The memory cell array 111 is divided into a plurality of memory blocks BK.

Each memory block includes a plurality of cell strings CS.

Each cell string CS includes a plurality of memory cells, e.g., 32 main cells or 32 redundant cells, which are coupled in series.

The cell strings CS are each coupled to bit lines BL and the memory blocks BL share the bit lines BL.

The X-decoder 112 may include a plurality of block selection circuits 112_1 each coupled to the memory blocks BK. Each block selection circuit 112_1 enables a voltage supply circuit 140 to transfer operation voltages into its corresponding memory block BK in response to an address signal provided from the control logic circuit 160.

The page buffer group 113 includes page buffers PB, each of which is coupled to one or more bit lines BL.

Each page buffer PB operates to program or read data.

The input/output circuit 114 is provided for controlling data input/output between the page buffer group 113 and the input/output pads group 150. The input/output circuit 114 enables data to be input/output by selecting one of the page buffers PB, which is coupled to the main cell array 111a or the redundant cell array 111b, in response to a repair signal provided from the repair circuit 130 and a control signal provided from the control logic circuit 160. For this function, the input/output circuit 114 includes a multiplexer (not shown) that permits one of the page buffers PB, which are coupled to the main and redundant cell arrays 111a and 111b, to input/output data.

The second plane 120 is structured in a manner similar to the first plane 110.

The repair circuit 130 compares address information, which is provided from the control logic circuit 160, with repair address information that has been preliminarily reserved, and generates the repair signal according to a result of the comparison.

The voltage supply circuit 140 generates operation voltages in response to a control signal provided from the control logic circuit 140. These operation voltages are a program voltage Vpgm, a pass voltage Vpass, a read voltage Vread, etc.

The control logic circuit 150 generates control signals to control operations of programming, reading, erasing and so on.

Additionally, in the semiconductor memory device 100, the input/output circuit 114 is coupled with the input/output pads group 150 for data input/output with an external system (not shown).

The input/output pads group 150 is commonly coupled to the first and second planes 110 and 120.

As stated above, in the general semiconductor memory device 100, the first and second planes, 110 and 120, are independently equipped with their own input/output circuits 114 and 124, but share a single input/output pads group 150.

A larger number of the planes cause a larger number of the input/output circuits 114, which results in an extension of circuit area. Further, an increase in the number of the input/output circuits 114 is inevitably accompanied with an extension of interconnection lines led to the input/output pads group 150.

Therefore, the present invention provides a new feature of semiconductor memory device in which planes share an input/output circuit.

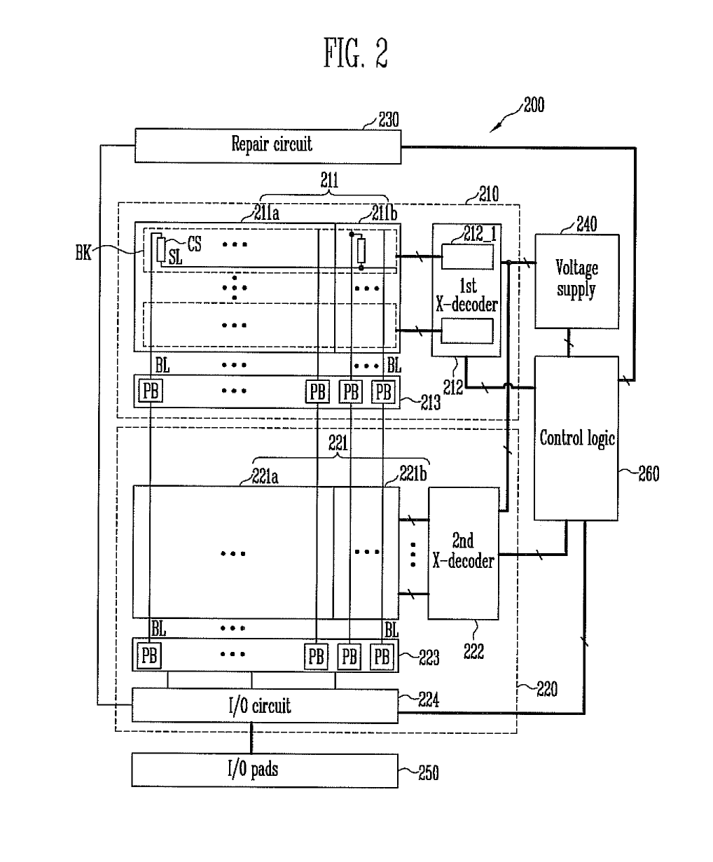

FIG. 2 illustrates a semiconductor memory device according to a first exemplary embodiment of the present invention.

Referring to FIG. 2, the semiconductor memory device 200 is comprised of a first plane 210, a second plane 220, a repair circuit 230, a voltage supply circuit 240, an input/output pads group 250, and a control logic circuit 260.

The first plane 210 includes a first memory cell array 211, a first X-decoder 212 and a first page buffer group 213.

The second plane 220 includes a second memory cell array 221, a second X-decoder 222, a second page buffer group 223 and an input/output circuit 224.

The first memory cell array 211 includes a plurality of memory blocks BK.

Each memory block BL is divided into a main cell array 211a and a redundant cell array 211b. The main cell array 211a of the memory block BK may include a plurality of cell strings, each cell string containing main cells coupled in series. The redundant cell array 211b may include a plurality of cell strings, each cell string containing redundant cells coupled in series. The main and redundant cells are similar in structure.

The first X-decoder 212 includes block selection circuits 212_1 coupled respectively to the memory blocks BK. Each block selection circuit 212_1 enables an operation voltage of the voltage supply circuit 240 to be transferred into its corresponding memory block BK in response to an address signal provided from the control logic circuit 260.

The first page buffer group 213 includes page buffers PB, each of which is coupled to one or more bit lines BL.

The second memory cell array 221, the second X-decoder 222 and the second page buffer group 223 of the second plane 220 are similar in structure to those of the first plane 210.

The input/output circuit 224 is provided to control data input/output between the first and second buffer groups, 213 and 223, and the input/output pads group 250. For this function, the first and second planes, 210 and 220, share the bit lines BL. For example, one bit line BL is commonly connected to the page buffers PB of the first and second page buffer groups 213 and 223.

The repair circuit 230 determines whether address information provided from the control logic circuit 260 has been repaired, and then outputs a repair signal according to a result of the determination. The repair signal is applied to the input/output circuit 224.

The voltage supply circuit 240 generates operation voltages. These operation voltages are a program voltage Vpgm, a pass voltage Vpass, a read voltage Vread, etc.

The input/output pads group 250 is composed of a plurality of pads. The semiconductor memory device 200 is coupled with an external system (not shown) by way of the pads. The pads are electrically connected to the input/output circuit 224.

The control logic circuit 260 generates control signals for operations of programming, reading, and so on.

The semiconductor memory device 200 according to the first embodiment is able to input/output data into/from these two planes 210 and 220 by means of the single input/output circuit 224. Although there is included more planes than two, the input/output circuit 224 may be sufficient in conducting the data input/output operation.

Since the first plane 210 does not have an input/output circuit 224, it uses the second page buffer group 223 in order to store data into the page buffers PB of the first page buffer group 213.

In more detail, inputting data into the first page buffer group 213 is carried out by providing data to the second page buffer group 223 through the input/output circuit 224.

Then, the data stored in the second page buffer group 223 are transferred to the first page buffer group 213 by way of the bit lines BL that are shared with the first and second planes.

Outputting data from the first page buffer group 213 is carried out by transferring data to the second buffer group 223 through the bit lines BL.

Then, the data stored in the second page buffer group 223 are output through the input/output circuit 224.

In the semiconductor memory device 200 according to the present invention, the first memory array 211 and the first page buffer group 213, and the second memory array 221 and the second page buffer group 223 are coupled together by way of switching elements. The switching element is preferably formed of a high voltage transistor that is endurable against a high voltage so as to protect the first page buffer group 213 or the second page buffer group 223 from high voltage.

Further, a semiconductor memory device 300 according to a second exemplary embodiment of the present invention is configured so that high voltage transistors are prepared in the least number and the input/output circuit is shared by a plurality of planes.

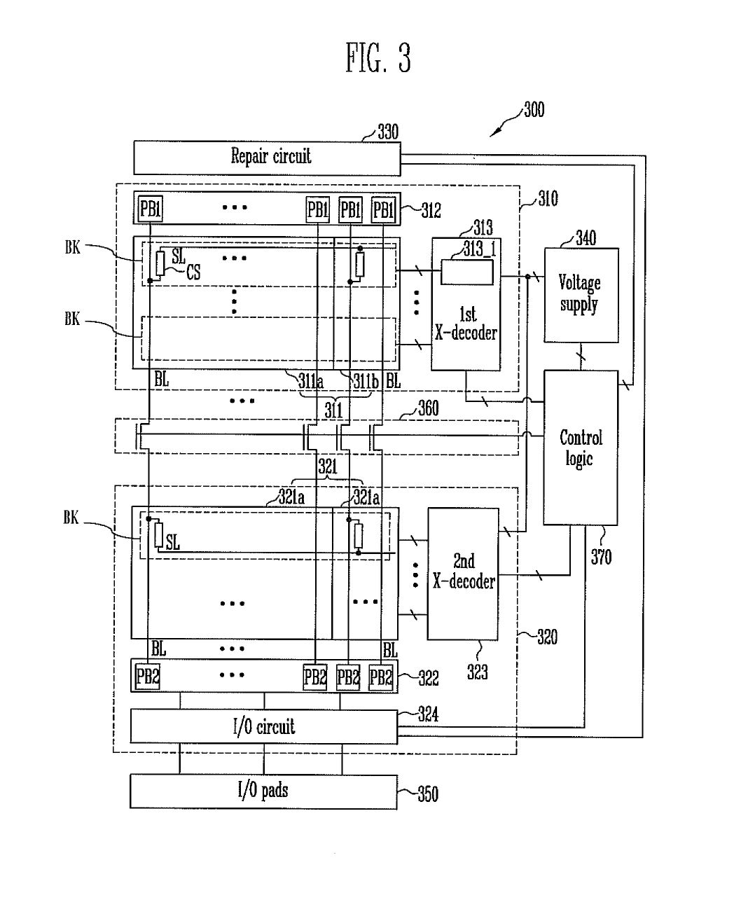

FIG. 3 illustrates the semiconductor memory device 300 according to the second exemplary embodiment of the present invention.

Referring to FIG. 3, the semiconductor memory device 300 is comprised of first and second planes 310 and 320, a repair circuit 330, a voltage supply circuit 340, an input/output pads group 350, a bit-line connection circuit 360, and a control logic circuit 370.

The first plane 310 includes a first memory cell array 311, a first page buffer group 312, and a first X-decoder 313.

The second plane 320 includes a second memory cell array 321, a second page buffer group 322, a second X-decoder 313 and an input/output circuit 324. The first and second planes, 310 and 320, are formed in the same well.

The first memory cell array 311 includes a plurality of memory blocks BK.

Each memory block BK is divided into a main cell array 311a and a redundant cell array 311b. The main cell array 311a of a memory block BK includes a plurality of cell strings, each cell string containing main cells coupled in series. The redundant cell array 311b includes a plurality of cell strings, each cell string containing redundant cells coupled in series. The main and redundant cells are similar in structure.

The first X-decoder 313 includes block selection circuits 313_1 coupled respectively to the memory blocks BK. Each block selection circuit 313_1 enables an operation voltage of the voltage supply circuit 340 to be transferred into its corresponding memory block BK in response to an address signal provided from the control logic circuit 370.

The first memory cell array 311 is similar in formation to the second memory cell array 321. The first X-decoder 313 is also similar in structure to the second X-decoder 323.

The bit lines, coupled to the first and second page buffer groups 312 and 322, are electrically connected or disconnected to the bit-line connection circuit 360.

For this, the bit-line connection circuit 360 includes a plurality of switching elements interposed between the bit lines between the first and second planes 310 and 320. An interconnection feature among the first and second page buffer groups, 312 and 322, and the bit-line connection circuit 360 will be detailed later.

The repair circuit 330 determines whether address information provided from the control logic circuit 370 has been repaired, and then outputs a repair signal according to a result of the determination. The repair signal is applied to the input/output circuit 324.

The voltage supply circuit 340 generates operation voltages. These operation voltages are a program voltage Vpgm, a pass voltage Vpass, a read voltage Vread, etc.

The input/output pads group 350 is composed of a plurality of pads. The semiconductor memory device 300 is coupled with an external system (not shown) by way of the pads. The pads are electrically connected to the input/output circuit 324.

The control logic circuit 370 generates control signals for operations of programming, reading, and so on. Additionally, the control logic circuit 370 generates a connection control signal BLISO to control an operation of the bit-line connection circuit 360.

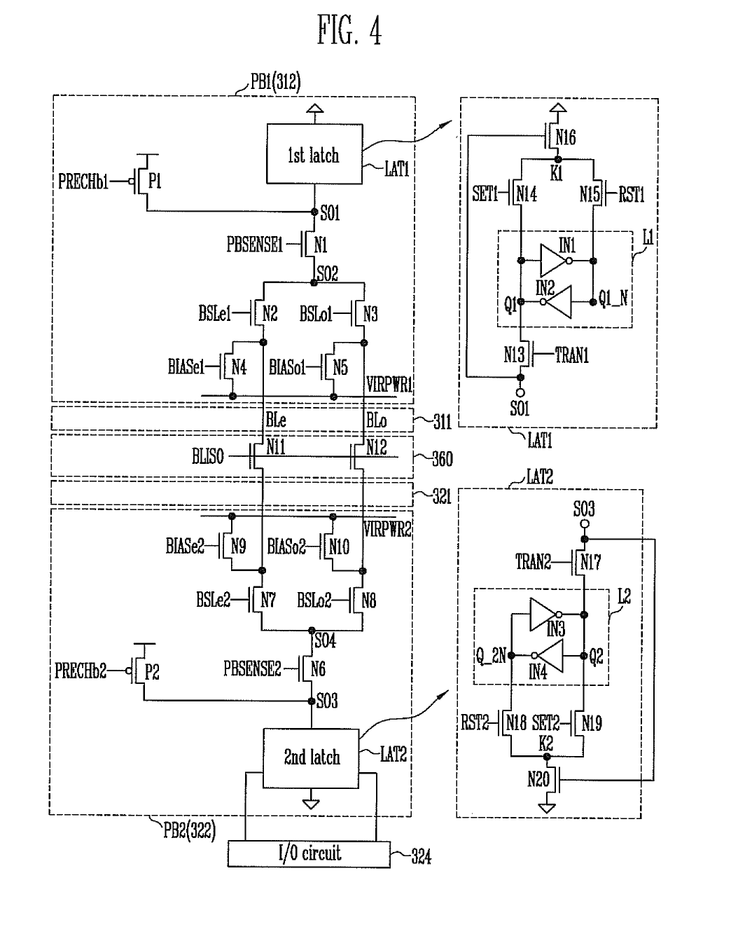

FIG. 4 illustrates in detail an interconnection feature among the first and second page buffer groups, and the bit-line connection circuit, of FIG. 3.

In FIG. 4, first and second page buffers PB1 and PB2 belonging respectively to the first and second page buffer groups 312 and 322, and a part of the bit-line connection circuit 360 for controlling bit line connection to the first and second page buffers PB1 and PB2 are shown. And, as depicted in FIG. 4, the bit lines BL are substantially classified into an even bit line BLe and an odd bit line BLo and the first and second page buffers, PB1 and PB2, are each coupled to a pair of the even and odd bit lines BLe and BLo.

Referring to FIG. 4, the first page buffer PB1 is similar in circuit structure to the second page buffer PB2.

The first page buffer PB1 is exemplarily composed of a first PMOS transistor P1, first through fifth NMOS transistor N1-N5 and a first latch circuit LAT1.

The second page buffer PB2 is exemplarily composed of a second PMOS transistor P2, sixth through tenth transistors N6-N10 and a second latch circuit LAT2. The second latch circuit LAT2 is coupled to the input/output circuit 324.

Typically for the second page buffer PB2, the second transistor P2 is provided to precharge a third sensing node S03. The second PMOS transistor P2 is electrically connected between a voltage terminal and the third sensing node S03. To the gate of the second PMOS transistor P2 is applied a second precharge-control signal PRECHb2.

The sixth NMOS transistor N6 is provided to electrically connect the third sensing node 503 with the fourth sensing node S04. The sixth NMOS transistor N6 is coupled between the third sensing node 503 and a fourth sensing node 504. To the gate of the sixth NMOS transistor N6 is applied a second sensing signal PBSENSE2.

The seventh and eighth NMOS transistors N7 and N8 act to electrically connect the even and odd bit lines BLe and BLo respectively with the fourth sensing node S04.

The seventh NMOS transistor N7 is coupled between the even bit line BLe and the fourth sensing node S04, and the eight NMOS transistor BLo is coupled between the odd bit line BLo and the fourth sensing node S04.

To the gate of the seventh NMOS transistor N7 is applied a second even bit-line selection signal BSLe. To the gate of the eighth NMOS transistor N8 is applied a second odd bit-line selection signal BSLo.

The ninth and tenth NMOS transistors, N9 and N10, transfers a second variable voltage VIRPWR2 to the even and odd bit lines BLe and BLo respectively.

The ninth NMOS transistor N9 is coupled between the even bit line BLe and a line through which the second variable voltage VIRPWR2 is supplied. The tenth NMOS transistor N10 is coupled between the odd bit line BLo and the supply line of the second variable voltage VIRPWR2.

To the gate of the ninth NMOS transistor N9 is applied a second even voltage-control signal BIASe2. To the gate of the tenth NMOS transistor N10 is applied to a second odd voltage-control signal BIASo2.

The second variable voltage VIRPWR2 is a voltage that ranges from the power voltage to the ground voltage to control a voltage of the bit line.

The first page buffer PB1 is similar in circuit formation to the second page buffer PB2.

The first latch circuit LAT1 is also similar in circuit formation to the second latch circuit LAT2. The first latch circuit LAT1 is exemplarily composed of thirteenth through sixteenth NMOS transistors N13-N16, and first and second inverters IN1 and IN2.

The thirteenth NMOS transistor N13 is coupled between the first sensing node S01 and a node Q1. To the gate of the thirteen NMOS transistor N13 is applied a first transmission control signal TRAN1.

The first and second inverters, IN1 and IN2, form the first latch L1 interposed between the node Q1_N and its counter node Q1.

The fourteenth NMOS transistor N14 is coupled between the node Q1_N and a node K1. To the gate of the fourteenth NMOS transistor N14 is applied a first set signal SET1.

The fifteenth NMOS transistor N15 is coupled between the node Q1 and the node K1. To the gate of the fifteenth NMOS transistor N15 is applied a first reset signal RST1.

With the fourteenth and fifteenth NMOS transistors N14 and N15, data of the latch L1 can be changed or retained.

The sixteenth NMOS transistor N16 is coupled between the node K1 and the ground node. The gate of the sixteenth NMOS transistor N16 links to the first sensing node S01.

The sixteenth NMOS transistor N16 electrically connects the node K1 to the ground node in accordance with a voltage level of the first sensing node S01. If the node K1 is electrically connected to the ground node, data of the latch L1 can be changed by means of the fourteenth and fifteenth transistors N14 and N15.

The second latch circuit LAT2 is similar in circuit formation to the first latch circuit LAT1. The second latch circuit LAT2 is exemplarily composed of seventeenth through twentieth NMOS transistors N17-N20, and third and fourth inverters IN3 and IN4. Since the second latch circuit LAT2 is similar in circuit configuration to the first latch circuit LAT1, it will not be described in more detail.

In the meantime, eleventh and twelfth NMOS transistors N11 and N12 of the bit-line connection circuit 360 electrically connect the even and odd bit lines, which are led to the first page buffer PB1, with the even and odd bit lines, which are led to the second page buffer PB2, in response to the connection control signal BLISO.

As the first and second planes 310 and 320 are formed in the same well, the eleventh and twelfth NMOS transistors N11 and N12 may be made up even with ordinaries, not firmly with specifics for high voltage.

A way of transferring data between the first and second page buffers PB1 and PB2 is as follows.

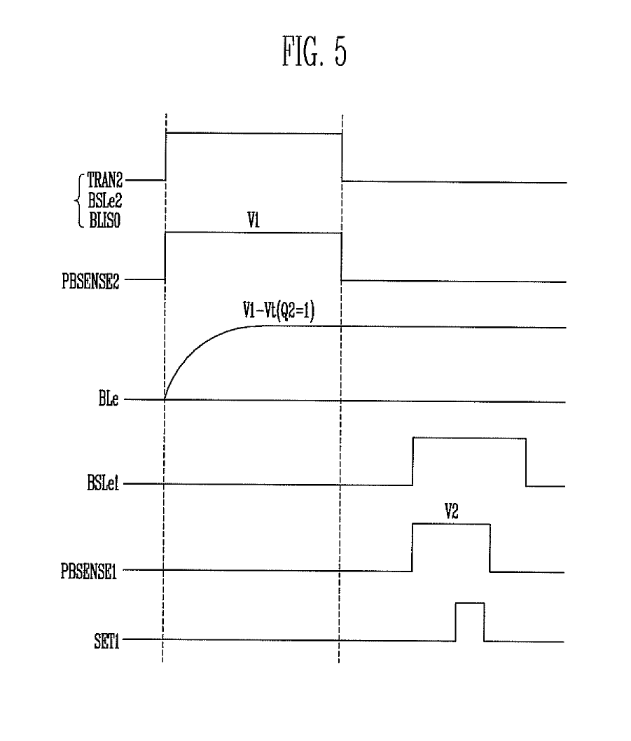

FIG. 5 depicts a timing diagram for describing data transmission between the first and second page buffers of FIG. 4.

In describing FIG. 5, reference will be made to FIGS. 3 and 4.

The timing diagram of FIG. 5 shows signal waveforms while transferring data from the latch L2 of the second latch circuit LAT2 of the second page buffer PB2 into the first page buffer PB2.

Referring to FIG. 5, for data transmission, the control logic circuit 370 first applies a second transfer control signal TRAN2 and the connection control signal BLISO, which are in high levels, and the second sensing signal PBSENSE2 of a first voltage level V1 to the second page buffer PB2.

The second transfer control signal TRAN2 with high level turns the seventeenth NMOS transistor N17 on and the second sensing signal PBSENSE2 with the first voltage level V1 turns the sixth NMOS transistor N6 on.

Accordingly, as the seventeenth NMOS transistor N17 is turned on, data of a node Q2 is transferred into the third sensing node S03.

If the node Q2 has a state of ‘1’, i.e., on a high level, a high level signal is transferred to the third sensing node 503. And, responding to the second sensing signal PBSENSE2 of the first voltage level V1, the sixth NMOS transistor N6 transfers a voltage by V1-Vt to the fourth sensing node S04. Here, Vt refers to the threshold voltage of the sixth NMOS transistor N6.

To transfer data through the even bit line BLe, the control logic circuit 370 also applies a second even bit-line selection signal BSLe2 of high level to the second page buffer PBZ. Thus, the even bit line BLe is precharged to the voltage level of V1-Vt.

As the connection control signal BLSO is set on a high level, the even bit line BLe coupled to the first page buffer PB1 is precharged up to the level of V1-Vt.

Additionally, the control logic circuit 370 precharges the first sensing node S01 to the power voltage level. Then, the control logic circuit 370 changes the second even bit-line selection signal BSLe2, the connection control signal BLISO and the second sensing signal PBSENSE2 into low levels, and outputs a first even bit-line selection signal BSLe1 of high level and a first sensing signal PBSENSE1 of a second voltage level V2. The second voltage level V2 is equal to or lower than the first voltage level V1.

Therefore, the first sensing node S01 is in the precharged state with the power voltage level and the even bit line BLe is charged at the level of V1-Vt. If the first sensing signal PBSENSE1 is applied to the gate of the first NMOS transistor N1, the first NMOS transistor N1 is kept on its turn-off state. Thus, the first sensing node S01 is held on the precharged state.

As the first sensing node S01 remains in the precharged state, the sixteenth NMOS transistor N16 is turned on to conductively connect the node K1 to the ground node.

If the first set signal SET1 is applied to the gate of the fourteenth NMOS transistor N14, the node Q1 is conductive to the node K1. Accordingly, the node Q1 is set on ‘0’. As a result, data is transferred from a second latch L2 of the second latch circuit LAT2 into the first latch L1 of the first latch circuit LAT1.

For data transmission from the first latch L1 to the input/output pads group 350, data is transferred from the first latch L1 into the second latch L2 in a reverse direction of the data flow shown in FIG. 5. During this, the input/output circuit 324 coupled to the second latch L2 operates to transfer data from the second latch L2 to the input/output pads group 350.

The semiconductor memory devices according to the first and second exemplary embodiments are shown as being equipped with a single input/output circuit even for two planes, reducing the number of input/output circuits. Therefore, it saves a circuit area occupied by the input/output circuit.

It is also permissible to share a single input/output circuit in a semiconductor memory device including more than two planes. Further, it is still permissible to configure a single input/output circuit to be shared by planes in the unit of two or three. With any manner of forming such an input/output logic system, it is possible to reduce a circuit area of input/output circuit because the number of the input/output circuits is smaller than that of the planes.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings and advantages. Accordingly, all such modifications are intended to be included within the scope of this invention as defined in the claims.

What is claimed is:

1. A semiconductor memory device comprising:
first and second planes each comprising a memory cell array that includes a plurality of memory cells coupled to bit lines, and page buffer groups that are coupled respectively to one or more of the bit lines and each include page buffers; and
a common input/output circuit shared by the page buffer groups of the first and second planes for data input/output control, and coupled to data input/output pads.

2. A semiconductor memory device comprising:
a first plane comprising a first memory cell array that includes a plurality of first memory cells coupled to bit lines, and a first page buffer group that is coupled to one or more of the bit lines and has page buffers; and
a second plane comprising a second memory cell array that includes a plurality of second memory cells coupled to the bit lines, a second page buffer group that is coupled to one or more of the bit lines and includes page buffers, and an input/output circuit coupled between the second page buffer group and data input/output pads to control data input/output,
wherein the first and second memory cells share the bit lines.

3. The semiconductor memory device of claim 2, wherein the first page buffer group is configured to receive and transfer data from and to the second page buffer group through the bit lines.

4. The semiconductor memory device of claim 2, wherein the first and second planes are independently formed in different wells, wherein sensing nodes belonging each to the first and second page buffers are jointly coupled to the bit line and electrically connected or disconnected through a switching element.

5. A semiconductor memory device comprising:
a first plane that comprises a first memory cell array including a plurality of first memory cells, and a first page buffer group including page buffers coupled to first bit lines to which the first memory cells are electrically connected;
a second plane that comprises a second memory cell array including a plurality of second memory cells, a second page buffer group including page buffers coupled to second bit lines to which the second memory cells are electrically connected, and an input/output circuit coupled between the second page buffer group and data input/output pads for data input/output control; and
a bit-line connection circuit configured to electrically connect the first bit lines with the second bit lines in response to a control signal.

6. The semiconductor memory device of claim 5, wherein the bit-line connection circuit electrically connects the first bit line with the second bit line and data is transferred between the first and second page buffer groups.

7. The semiconductor memory device of claim 5, wherein the first and second planes are formed in the same well and the bit-line connection circuit comprises switching elements that are interposed between the first and second bit lines.

8. A method of programming a semiconductor memory device, the method comprising:
inputting data, which is to be programmed into a first plane, into a second page buffer group included in a second plane;
transferring data from the second page buffer group to a first page buffer group of the first plane through bit lines that are jointly coupled to the first and second planes; and
programming the first plane with data that are transferred into the first page buffer group.

9. The method of claim 8, wherein transferring the data comprises:
changing voltages of the bit lines coupled respectively by the data that have been input into the second page buffer group; and
sensing the changed bit-line voltage and storing the sensed data into the first page buffer group.

10. The method of claim 8, which further comprises:
inputting data, which are to be programmed into the second plane, into the second page buffer group; and
programming the second plane with the data stored in the second page buffer group.

11. A method of reading a semiconductor memory device, the method comprising:
reading data from a selected page of a first plane and storing the read data into a first page buffer group of the first plane;
transferring the read data from the first page buffer group to a second page buffer group of a second plane through bit lines that are jointly coupled to the first and second planes; and
outputting the transferred data to an external system from the second page buffer group through an input/output circuit that is included in the second plane.

12. The method of claim 11, wherein transferring the data comprises:
changing voltages of the bit lines coupled respectively by the data that have been input into the second page buffer group; and
storing data, which are sensed through the bit lines with the changed voltages, into the first page buffer group.

13. The method of claim 12, further comprising:
reading data from a selected page of a second plane and storing the read data into the second page buffer group; and
outputting the read data to an external system from the second page buffer group through the input/output circuit.
